(19) United States
(12) Patent Application Publication
(10) Pub. No.: US 2025/0015010 A1
(43) Pub. Date: Jan. 9, 2025

(54) SEMICONDUCTOR STRUCTURE AND FABRICATING METHOD THEREOF

(71) Applicant: Taiwan Semiconductor Manufacturing Company Limited, Hsin-Chu (TW)

(72) Inventors: Wang Kuo LIANG, Hsinchu City (TW); Chih-Yu TSENG, Hsinchu County (TW); Chung-Wen WENG, Hsinchu City (TW)

(21) Appl. No.: 18/218,222

(22) Filed: Jul. 5, 2023

(51) Int. Cl. H01L 23/544; H01L 21/027; H01L 21/311; H01L 23/58

(52) U.S. Cl. CPC H01L 23/544; H01L 21/0274; H01L 21/31144; H01L 23/585; H01L 2223/54426

(57) ABSTRACT

According to some embodiments of the disclosure, a semiconductor structure includes a first alignment region defined in a substrate layer and a first frame at edges of the first alignment region. A first alignment mark is in the first alignment region and bordered by the first frame. According to some embodiments of the disclosure, a method of fabricating a semiconductor structure includes forming an isolation structure over a substrate layer in a first alignment region. A process layer is formed over the isolation structure. A patterned mask is formed over the process layer. The process layer is patterned using the patterned mask as a template to form a first frame at edges of the first alignment region and a first alignment mark in the first alignment region and bordered by the first frame.

### BACKGROUND

The fabrication of microcircuit devices on a semiconductor wafer involves a number of steps where patterns are transferred from photolithographic masks on the wafer. The masking step includes an etching step and defines selected areas to be exposed on the wafer for subsequent processes such as oxidation, metal deposition, and impurity introduction.

In the production of integrate circuit structures, structures have a plurality of layers due to the ever increasing density of the circuit elements in the structure. Further, as the device and feature sizes become smaller, there is a need to align the photolithographic masks precisely with the wafer during the masking step to minimize misalignment between the layers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-3 are illustrations of a semiconductor structure at various stages of fabrication, in accordance with some embodiments.

FIGS. 4-6 are illustrations of a semiconductor structure at various stages of fabrication, in accordance with some embodiments.

FIGS. 7 and 8 are illustrations of a semiconductor structure at various stages of fabrication, in accordance with some embodiments.

FIGS. 9-11 are illustrations of a semiconductor structure at various stages of fabrication, in accordance with some embodiments.

FIGS. 12 and 13 are illustrations of a semiconductor structure at various stages of fabrication, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above.” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

During the fabrication of the integrated circuit structures, a number of device layers and metallization layers are formed. The metallization layers are formed over the device layers and provide interconnections for the devices in the device layers. Each of the metallization layers is typically separated from another metallization layer by an insulating layer. Alignment marks are used for aligning a semiconductor wafer when a process operation is performed by a process tool, such as a photolithography tool. Using feedback measurements regarding the alignment of the second box relative to the first box, a controller for the photolithography tool in the photolithography process may be adjusted for a subsequent wafer being processed. For example, a parameter in an operating recipe of the photolithography tool may be adjusted to attempt to reduce the overlay error. In some embodiments, if the overlay error exceeds a fault threshold, the measured wafer may be designated as being defective. The defective wafer may be scrapped or the defective wafer may be reworked by removing one or more layers used in the patterning process, replacing the layers, and re-patterning the wafer to attempt to correct the overlay error.

Many photolithography steps are necessary to form the devices and the metallization structures. A semiconductor structure may include a semiconductor wafer, active and passive devices formed within the wafer, and insulating and conductive layers formed over a wafer surface of the semiconductor wafer. A semiconductor wafer is typically divided into product regions and at least one alignment region. The product regions and the at least one alignment region may be referred to as tiles. Product regions are the regions where integrated circuits are formed. For example, the product regions include at least one integrated circuit therein, in which the integrated circuit may include a plurality of semiconductor components, such as resistors, inductors, and capacitors. The alignment region is where alignment marks (e.g., raised patterns or recessed trenches) are formed. The alignment region may have any shape, such as in a shape of a rectangular tile.

The alignment region may neighbor some of the product regions. In some embodiments, the product regions are arranged in an array, and the alignment region is arranged between at least two of the product regions. Hence, some of the product regions are spaced apart by the alignment region. In some embodiments, the alignment region can be disposed along a cutting path of the semiconductor structure, in which a cutting tool cuts through the alignment region when the semiconductor substrate is cut to separate the product regions into separate semiconductor dies. In some embodiments, the alignment marks in the alignment region are cut and destroyed after the semiconductor substrate is cut. In some other embodiments, the alignment marks in the alignment region remain complete after the semiconductor substrate is cut.

According to some embodiments, an alignment region includes an alignment mark and a frame bordering the alignment region separate from the alignment mark. Differences in pitches in the features formed in product regions as compared to the features formed in the alignment regions can cause photoresist loading that results in critical dimension (CD) variation and reduced performance of optical proximity correction (OPC). The frame may be continuous or segmented. The segments of a segmented frame may be rectangular or circular. In some embodiments, two or more frames are provided in the alignment region around the alignment mark. The frame may be provided using the same tone as the alignment mark. For example, if the alignment mark is a raised feature (e.g., formed by lines patterned in a process layer), the frame may also be a raised feature. If the alignment mark is a recessed feature (e.g., formed by trenches in a process layer), the frame may also be a recessed feature. For two adjacent alignment regions, frame segments may be shared along a common edge. In an embodiment where the alignment region borders a product region, and the product region may include a seal ring, where the seal ring can serve as a segment of the frame along the common edge. Interfaces of the frame at the seal ring can provide an additional alignment reference for positioning stacked semiconductor wafers. For example, the frame-seal interface of a first semiconductor wafer may be aligned with the frame-seal interface of a second semiconductor wafer when the second semiconductor wafer is being placed by a stacking tool to vertically align the second semiconductor wafer with respect to the first semiconductor wafer. In some embodiments, the frame comprises a first layer, such as polysilicon, and a metal-containing second layer, such as a silicide, formed over the first layer and providing a top surface of the frame. A hybrid bonding process may be used for stacking semiconductor wafers. When temperature and/or heat are applied to two mated semiconductor wafers, similar materials on each semiconductor wafer form hybrid bonds with one another. For example, embedded copper contacts in the lower semiconductor wafer bond with embedded copper contacts in the upper semiconductor wafer and dielectric interfaces between the two wafers bond with one another. In some embodiments where the metal-containing layer in the frame from the lower semiconductor comprises a silicide material, the frame may form a hybrid bond with the bottom surface (e.g., silicon substrate layer) of the upper semiconductor wafer. Providing the frame around the alignment region and bordering the alignment mark can reduce photoresist loading, improve the alignment mark structure, and improve the alignment procedures performed using the alignment mark.

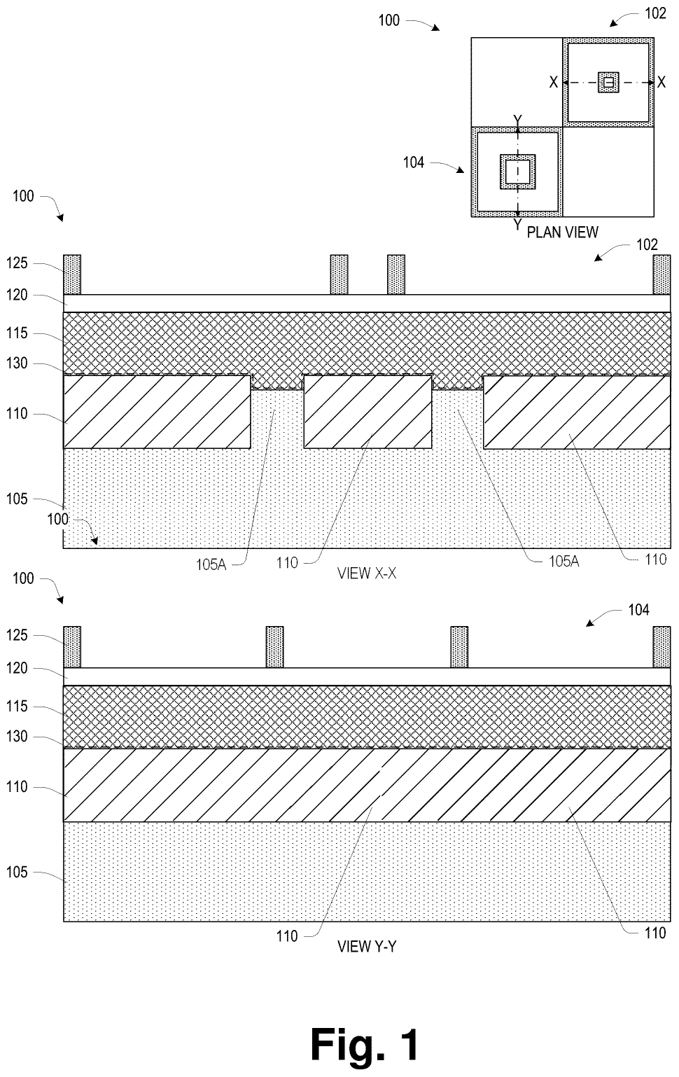

FIGS. 1-13 are illustrations of a semiconductor structure 100 at various stages of fabrication, in accordance with some embodiments. Some of the figures include a simplistic plan view showing where various cross-sectional views are taken. Referring to FIG. 1, the view X-X is a cross-sectional view of an alignment region 102 taken through the semiconductor structure 100 in a horizontal direction and the view Y-Y a cross-sectional view of an alignment region 104 taken through the semiconductor structure 100 in a vertical direction. Not all aspects of the processing shown in the cross-sectional views are depicted in the plan view.

Referring to FIG. 1, a plurality of layers used in the formation of the semiconductor structure 100 are illustrated, in accordance with some embodiments. The plurality of layers is formed over a substrate layer 105. In some embodiments, the substrate layer 105 is part of a substrate comprising at least one of an epitaxial layer, a single crystalline semiconductor material such as, but not limited to Si, Ge, SiGe, InGaAs, GaAs, InSb, GaP. GaSb, InAlAs, GaSbP, GaAsSb, and InP, a silicon-on-insulator (SOI) structure, a wafer, or a die formed from a wafer. In some embodiments, the substrate layer 105 comprises crystalline silicon.

In an embodiment, one or more shallow trench isolation (STI) structures 110 are formed within the substrate layer 105. Portions of the substrate layer 105 between the STI structures 110 define active regions 105A. In some embodiments, the STI structures 110 are formed by forming at least one mask layer over the substrate layer 105. In some embodiments, the mask layer comprises a layer of oxide material over the substrate layer 105, a layer of nitride material over the layer of oxide material, and/or one or more other suitable layers. At least some of the layers of the mask layer are removed to define an etch mask for use as a template to etch the substrate layer 105 to form trenches. A dielectric material is formed in the trenches to define the STI structures 110. In some embodiments, the STI structures 110 include multiple layers, such as an oxide liner, a nitride liner formed over the oxide liner, an oxide fill material formed over the nitride liner, and/or other suitable materials.

In some embodiments, the fill material, such as the oxide fill material, is formed using a high density (HDP) plasma process. The HDP process uses precursor gases comprising at least one of silane (SiH₄), oxygen, argon, or other suitable gases. The HDP process includes a deposition component, which forms material on surfaces defining the trench, and a sputtering component, which removes or relocates deposited material. A deposition-to-sputtering ratio depends on gas ratios employed during the deposition component. According to some embodiments, argon and oxygen act as sputtering sources, and the particular values of the gas ratios are determined based on an aspect ratio of the trench. After forming the fill material, an anneal process may be performed to densify the fill material. In some embodiments, the STI structures 110 generate compressive stress.

In some embodiments, the height of the STI structures 110 relative to the substrate layer 105 can vary. For example, the STI structures 110 can be recessed relative to the substrate layer 105 or the substrate layer 105 can be recessed relative to the STI structures 110 (as illustrated in FIG. 1). The relative heights at an interface of the STI structures 110 and the substrate layer 105 depend on the processes performed for forming the STI structures 110, such as at least one of deposition, planarization, mask removal, surface treatment, or other suitable techniques. Other structures and/or configurations of the STI structures 110 are within the scope of the present disclosure.

In some embodiments, a plurality of layers are formed over the substrate layer 105 and the STI structures 110. The layers may include a semiconductor layer 115, a cap layer 120, and a patterned mask 125. The semiconductor layer 115 and the cap layer 120 may be collectively referred to as a process layer. In some embodiments, the semiconductor layer 115 comprises polysilicon. The cap layer 120 may be a material that may be etched selectively to the material of the semiconductor layer 115. The cap layer 120 may be a dielectric layer, such as silicon nitride, or a metal-containing layer, such as a metal silicide. In some embodiments, the cap layer 120 is formed by depositing a conformal layer of a refractory metal over the semiconductor layer 115. The refractory metal may comprise at least one of nickel, platinum, cobalt, or other suitable materials. An annealing process may be performed to cause the refractory metal to react with underlying silicon-containing material to form a metal silicide, and an etch process may be performed to remove unreacted portions of the layer of refractory metal, according to some embodiments. An additional annealing process may be performed after removing the excess refractory metal to form a final phase of the metal silicide. The silicide formation process consumes some of the material of the semiconductor layer 115.

In some embodiments, the semiconductor layer 115 and the cap layer 120 are part of a gate stack that is used to form gate electrodes in a product region of the semiconductor structure 100. A gate insulation layer 130 (shown in phantom) may be formed under the semiconductor layer 115. In some embodiments, the gate insulation layer 130 comprises silicon and oxygen. The gate insulation layer 130 may comprise a high-k dielectric. As used herein, the term “high-k dielectric” refers to the material having a dielectric constant, k, greater than or equal to about 3.9, which is the k value of SiO₂. The material of the high-k dielectric layer may be any suitable material. Examples of the material of the high-k dielectric layer include but are not limited to Al₂O₃, HfO₂, ZrO₂, La₂O₃, TiO₂, SrTiO₃, LaAlO₃, Y₂O₃, Al₂OₓN_{y}, HfOₓN_{y}, ZrOₓN_{y}, La₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3, and each value of y is independently from 0 to 2. The gate insulation layer 130 may comprise a native oxide layer formed by exposure of the semiconductor structure 100 to oxygen at various points in the process flow, causing the formation of silicon dioxide on exposed surfaces of the substrate layer 105.

In some embodiments, the patterned mask 125 is formed from a photolithography stack, where the photolithography stack may comprise a bottom antireflective coating (BARC) layer formed over the cap layer 120. In some embodiments, the BARC layer is a polymer layer that is applied using a spin coating process. In some embodiments, the photolithography stack comprises an organic planarization layer (OPL) formed over the BARC layer. In some embodiments, the OPL layer comprises a photo-sensitive organic polymer that is applied using a spin coating process. In some embodiments, the OPL layer comprises a dielectric layer. In some embodiments, the photolithography stack comprises a photoresist layer over the OPL layer. In some embodiments, the photoresist layer comprises an electromagnetic radiation sensitive material and properties, such as solubility, of the photoresist layer are affected by electromagnetic radiation. The photoresist layer may be either a negative photoresist or a positive photoresist. In some embodiments, portions of the OPL layer are also irradiated by the electromagnetic radiation that patterns the photoresist layer to change the etch selectivity of the irradiated portions of the OPL layer with respect to non-irradiated portions. In some embodiments, the photoresist layer is exposed using a radiation source and a reticle to define a pattern in the photoresist layer. In some embodiments, portions of the photoresist layer are removed to define a patterned photoresist layer. In some embodiments, the underlying OPL layer and BARC layer are etched using the patterned photoresist layer as a template to form the patterned mask 125 over the cap layer 120.

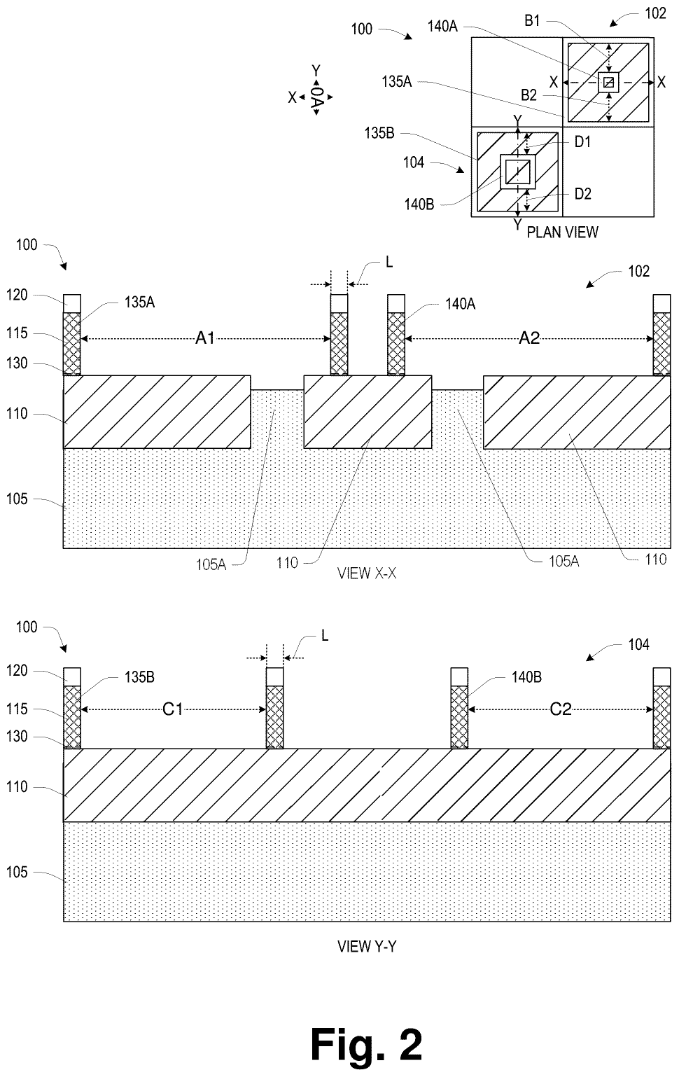

Referring to FIG. 2, the semiconductor layer 115 and the cap layer 120 are patterned to form frames 135A, 135B and alignment marks 140A, 140B, and the patterned mask 125 is removed, in accordance with some embodiments. According to some embodiments, the frames 135A, 135B and the alignment marks 140A, 140B are formed by performing an etch process using the patterned mask 125 as an etch template to pattern the cap layer 120 and the semiconductor layer 115 to form the frames 135A, 135B at edges of the alignment regions 102, 104 and to form the alignment marks 140A, 140B in the frames 135A, 135B.

In some embodiments, the positioning of the alignment marks 140A, 140B within the frames 135A, 135B meets the spacing limitations A1>5*L and A1-A2<0.5*A1 (same for B1/B2, C1/C2, and D1/D2, where L represents the width of the alignment marks 1240A, 140B, A1/A2 represent the horizontal spacing between the frame 135A and the alignment mark 140A on opposite sides of the alignment mark 140A, B1/B2 represent the vertical spacing between the frame 135A and the alignment mark 140A on opposite sides of the alignment mark 140A, C1/C2 represent the horizontal spacing between the frame 135B and the alignment mark 140B on opposite sides of the alignment mark 140B, and D1/D2 represent the vertical spacing between the frame 135B and the alignment mark 140B on opposite sides of the alignment mark 140B. The positioning of the alignment marks 140A, 140B within the frames 135A, 135B may be symmetric (A1=A2=B1=B2, C1-C2-D1=D2). Balancing the alignment marks 140A, 140B within the frames 135A, 135B improves at least one of photoresist loading, CD pitch stability, profile quality, or OPC effectiveness.

Referring to the plan view, alignment is performed in the plane defined by the x-axis (horizontal in the plan view) and the y-axis (vertical in the plan view). The alignment involves aligning two layers spaced apart along the z-axis (into or out of the page). For example, using a box-in-box alignment mark, a first box is formed in a first layer and a second box larger than the first box is formed in a second layer over the first layer in the z-direction. Alignment between the first layer and the second layer may be determined, in both the x-direction and the y-direction (defined by the x and y axes) by measuring an offset between the first box and the second box. If the first layer and the second layer are perfectly aligned in a particular direction, the space between the first box and the second box will be the same on both sides of the smaller of the first box and the second box. Differences between the offsets on the sides of the smaller of the first box and the second box represent overlay error or mis-registration. In some embodiments, the frame 135A and the alignment mark 140A may be formed in the first layer and a frame similar to the frame 135A and an alignment mark similar to the alignment mark 140B (e.g., larger than the alignment mark 140A) may be formed in the second layer over the first layer and over the alignment mark 140A. Offsets measured in the x-direction and the y-direction between the alignment mark 140A and the alignment mark similar to the alignment mark 140B may indicate the accuracy of the alignment process used for patterning the second layer relative to the first layer.

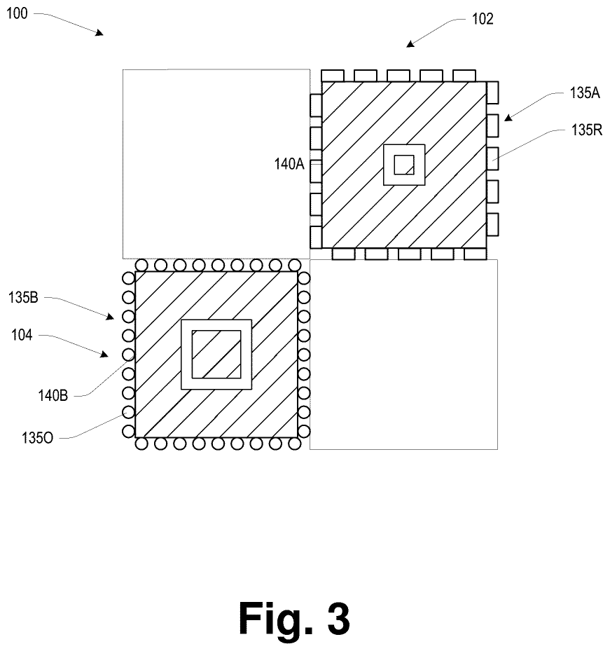

Referring to FIG. 3, a top view of the semiconductor structure 100 is provided, in accordance with some embodiments. The frames 135A, 135B may be continuous or segmented. FIG. 3 illustrates the frame 135A as being segmented and defined by a plurality of rectangular spaced segments 135R. The rectangular spaced segments 135R may also be square. FIG. 3 illustrates the frame 135B as being segmented and defined by a plurality of oval spaced segments 135O. The oval spaced segments 135O may also be circular. The two types of segmentation are provided for illustrative purposes. In some embodiments, both frames 135A, 135B have either rectangular spaced segments 135R, oval spaced segments 135O, or are otherwise similarly shaped.

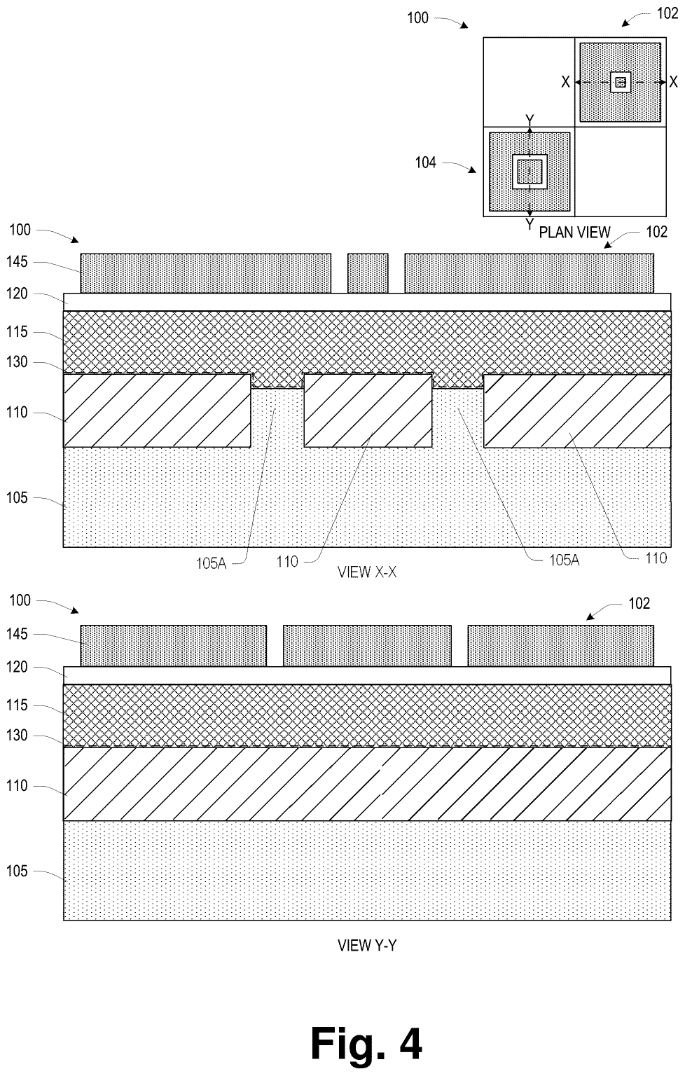

FIGS. 4-6 illustrate an embodiment of the semiconductor structure 100 with reverse tone alignment marks and frames, in accordance with some embodiments. Referring to FIG. 4, a patterned mask 145 is formed over the semiconductor layer 115 and the cap layer 120, in accordance with some embodiments. The patterned mask 145 may be formed from a photolithography stack including a BARC layer formed over the cap layer 120, an OPL formed over the BARC layer, and a photoresist layer over the OPL layer. In some embodiments, portions of the photoresist layer are removed to define a patterned photoresist layer. The underlying OPL layer and BARC layer are etched using the patterned photoresist layer as a template to form the patterned mask 145 over the cap layer 120.

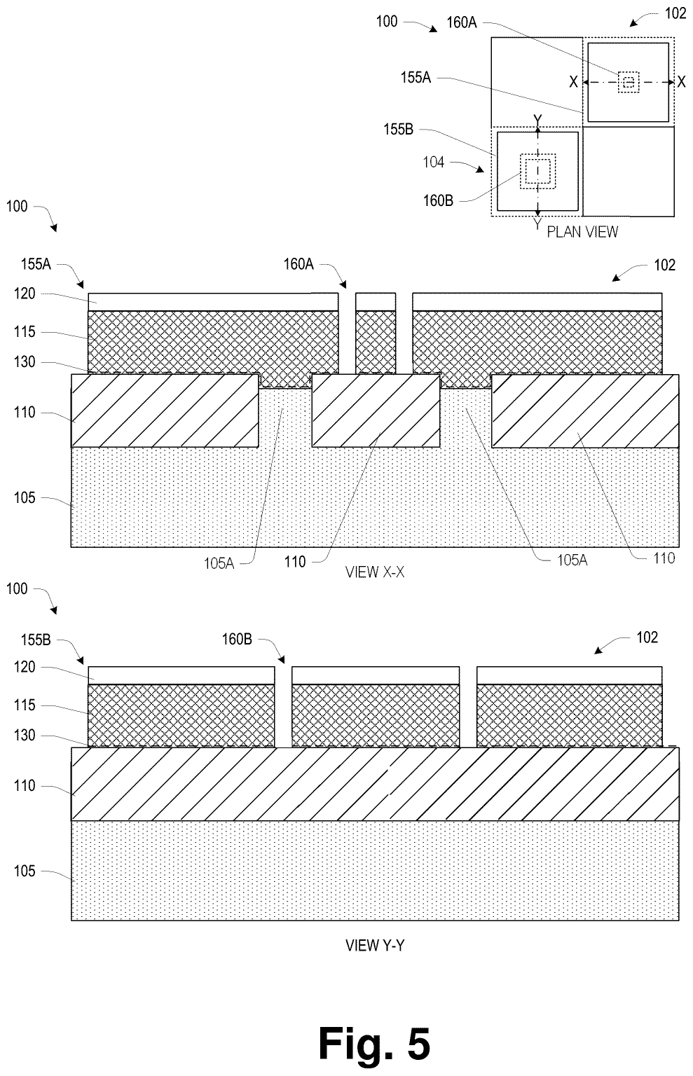

Referring to FIG. 5, the semiconductor layer 115 and the cap layer 120 are patterned to form frames 155A, 155B and alignment marks 160A, 160B, and the patterned mask 145 is removed, in accordance with some embodiments. According to some embodiments, the frames 155A, 155B and the alignment marks 160A, 160B are formed by performing an etch process using the patterned mask 145 as an etch template to pattern the cap layer 120 and the semiconductor layer 115 to form the frames 155A, 155B at edges of the alignment regions 102, 104 and to form the alignment marks 160A, 160B in the frames 155A, 155B.

The frames 155A, 155B and the alignment marks 160A, 160B have a reverse tone compared to the frames 135A, 135B and the alignment marks 140A, 140B of FIG. 2. That is, stated differently, the frames 155A, 155B and the alignment marks 160A, 160B are defined by trenches in the cap layer 120 and the semiconductor layer 115, thus making the frames 155A, 155B and the alignment marks 160A, 160B have the reverse tone compared to the frames 135A, 135B and the alignment marks 140A. 140B of FIG. 2.

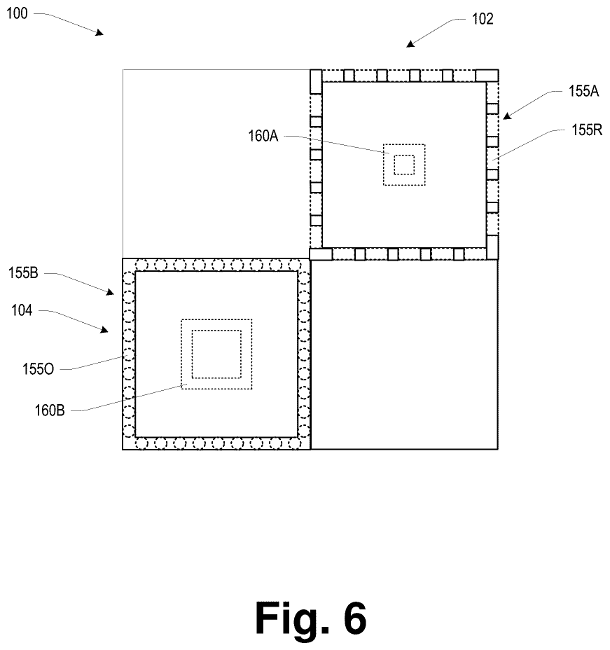

Referring to FIG. 6, a top view of the semiconductor structure 100 is provided, in accordance with some embodiments. The frames 155A, 155B may be continuous or segmented. FIG. 6 illustrates the frame 155A as being segmented and defined by a plurality of rectangular spaced recesses 155R in the cap layer 120 and the semiconductor layer 115. The rectangular spaced recesses 155R may also be square. FIG. 6 illustrates the frame 155B as being segmented and defined by a plurality of oval spaced recesses 155O in the cap layer 120 and the semiconductor layer 115. The oval spaced recesses 155O may also be circular. The two types of segmentation are provided for illustrative purposes. In some embodiments, both frames 155A, 155B have either rectangular spaced recesses 155R, oval spaced recesses 155O, or are otherwise similarly shaped.

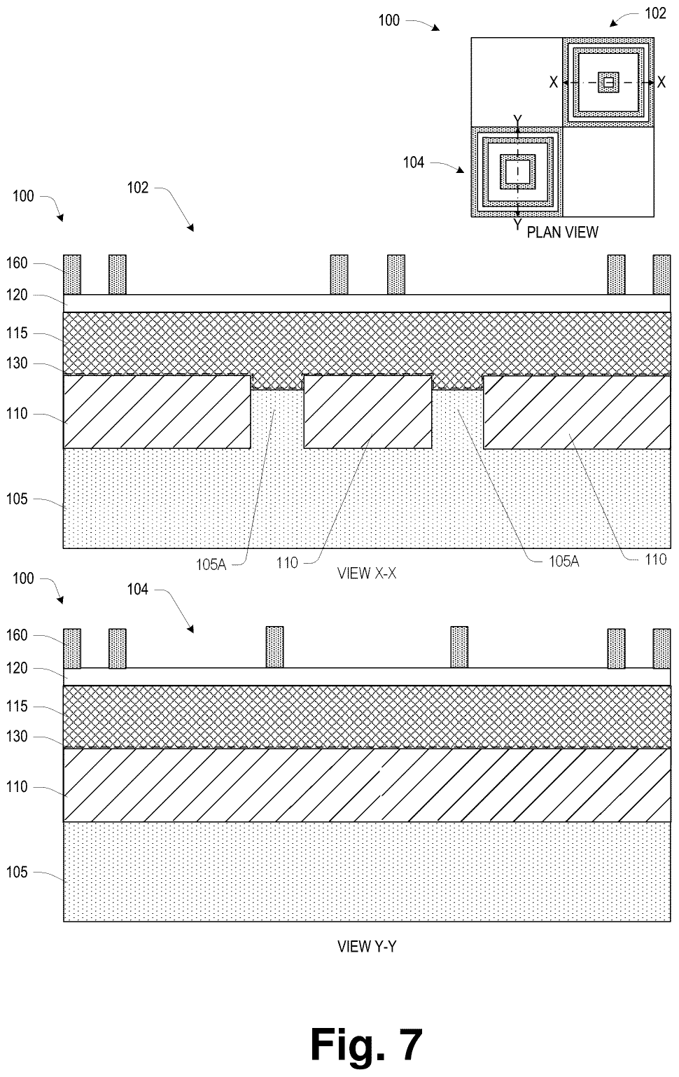

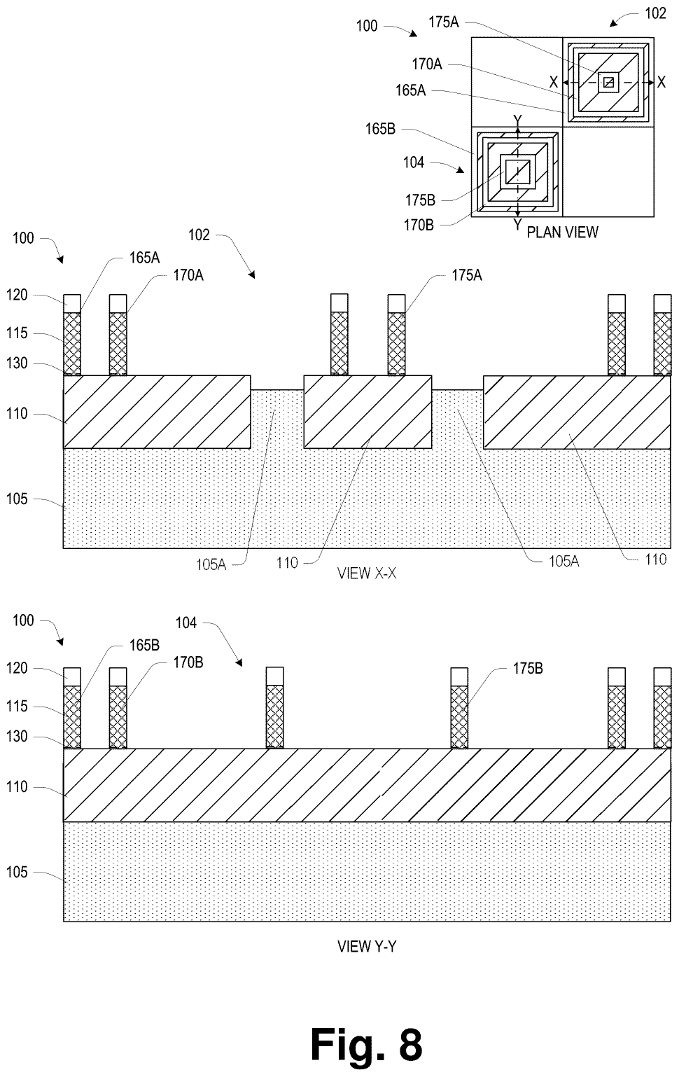

FIGS. 7 and 8 illustrate an embodiment of the semiconductor structure 100 with multiple frames, in accordance with some embodiments. Referring to FIG. 7, a patterned mask 160 is formed over the semiconductor layer 115 and the cap layer 120, in accordance with some embodiments. The patterned mask 160 may be formed from a photolithography stack including a BARC layer formed over the cap layer 120, an OPL formed over the BARC layer, and a photoresist layer over the OPL layer. In some embodiments, portions of the photoresist layer are removed to define a patterned photoresist layer. The underlying OPL layer and BARC layer are etched using the patterned photoresist layer as a template to form the patterned mask 160 over the cap layer 120.

Referring to FIG. 8, the semiconductor layer 115 and the cap layer 120 are patterned to form outer frames 165A, 165B, inner frames 170A, 170B, and alignment marks 175A, 175B, and the patterned mask 160 is removed, in accordance with some embodiments. In some embodiments, the frames 165A, 165B, 170A, 170B and the alignment marks 175A, 175B are formed by performing an etch process using the patterned mask 160 as an etch template to pattern the cap layer 120 and the semiconductor layer 115 to define the frames 165A, 165B, 170A, 170B and the alignment marks 175A, 175B. The number of frames 165A, 165B, 170A, 170B may vary. Providing multiple frames 165A, 165B, 170A, 170B can further improve at least one of photoresist loading, CD pitch stability, profile quality, or OPC effectiveness. The frames 165A, 165B, 170A, 170B may be raised features as illustrated in FIGS. 1-3, 7, and 8 or recessed features as illustrated in FIGS. 4-6. The frames 165A, 165B, 170A, 170B may be continuous or segmented.

FIGS. 1-8 illustrate alignment marks employing a box-in-box configuration. A first box is formed on a first layer and a second box is formed on the next layer. One of the boxes is larger than the other. Alignment of the second layer to the first layer may be determined by measuring the offsets between the first box and the second box, in either the x-direction or the y-direction. Other types of alignment marks may be used, such as bar-in-bar marks (where a first set of bars is formed in a first layer and a second set of bars parallel to but spaced further apart compared to the first set of bars is formed in a second layer), multi-hole marks (where overlapping holes are formed in subsequent layers), grid alignment marks (AIM) (where the alignment mark includes grids of raised or recessed features oriented along the x-direction adjacent grids oriented along the y-direction), or some other type of alignment mark.

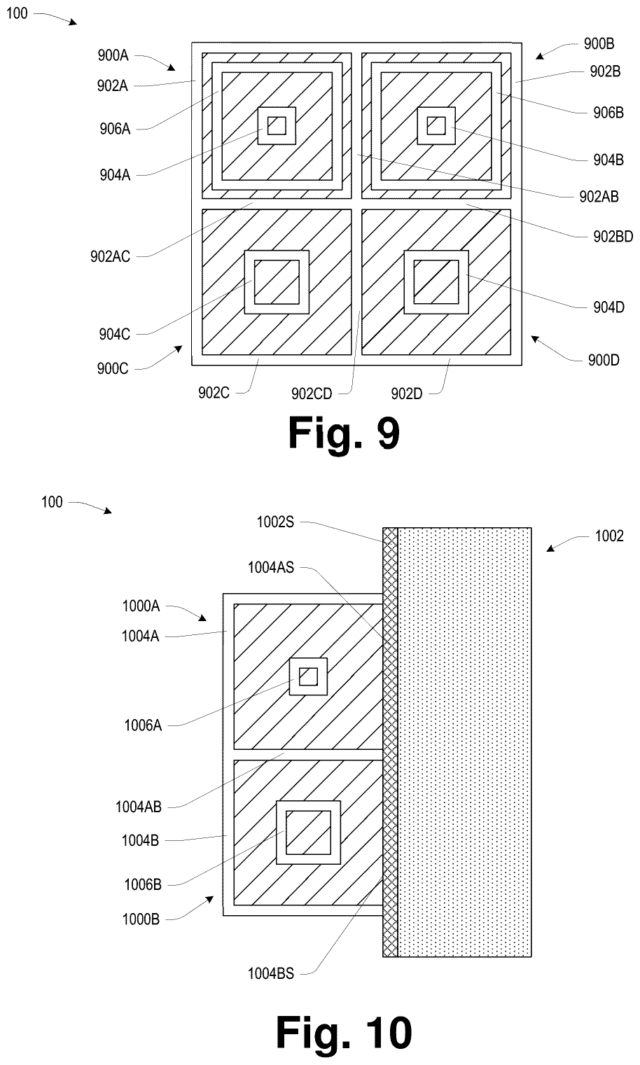

FIGS. 9-11 illustrate embodiments of the semiconductor structure 100 with alignment regions having at least a portion of the frame shared with an adjacent region, in accordance with some embodiments. Referring to FIG. 9, the semiconductor structure 100 includes alignment regions 900A, 900B, 900C, 900D with shared frame segments, in accordance with some embodiments. The alignment regions 900A, 900B, 900C, 900D include frames 902A, 902B, 902C, 902D at the edges of the alignment regions 900A, 900B, 900C, 900D and alignment marks 904A, 904B, 904C, 904D inside the frames 902A, 902B, 902C, 902D. The alignment regions 900A, 900B include inner frames 906A, 906B. Where the alignment regions 900A. 900B, 900C, 900D abut one another, the outer frames 902A, 902B, 902C, 902D have shared frame segments 902AB, 902AC, 902BD, 902CD. For example, where the alignment regions 900A, 900B abut one another in the horizontal direction, the frame segment 902AB is shared by both alignment regions 900A, 900B. Similarly, where the alignment regions 900A, 900C abut one another in the vertical direction, the frame segment 902AC is shared by both alignment regions. The shared frame segments 902AB, 902AC, 902BD, 902CD may provide a consistent line width for the frames 902A, 902B, 902C, 902D.

Referring to FIG. 10, the semiconductor structure 100 includes alignment regions 1000A, 1000B abutting a product region 1002, in accordance with some embodiments. The product region 1002 comprises a seal ring 1002S and one or more semiconductor devices, such as memory devices, logic devices, etc. The alignment regions 1000A, 1000B include frames 1004A, 1004B at the edges of the alignment regions 1000A, 1000B and alignment marks 1006A, 1006B inside the frames 1004A, 1004B. Where the alignment regions 1000A, 1000B abut one another in the vertical direction, the frame segment 1004AB is shared by both alignment regions 1000A, 1000B. Where the alignment regions 1000A, 1000B abut the product region 1002, portions of the seal ring 1002S define frame segments 1004AS, 1004BS of the frames 1004A, 1004B.

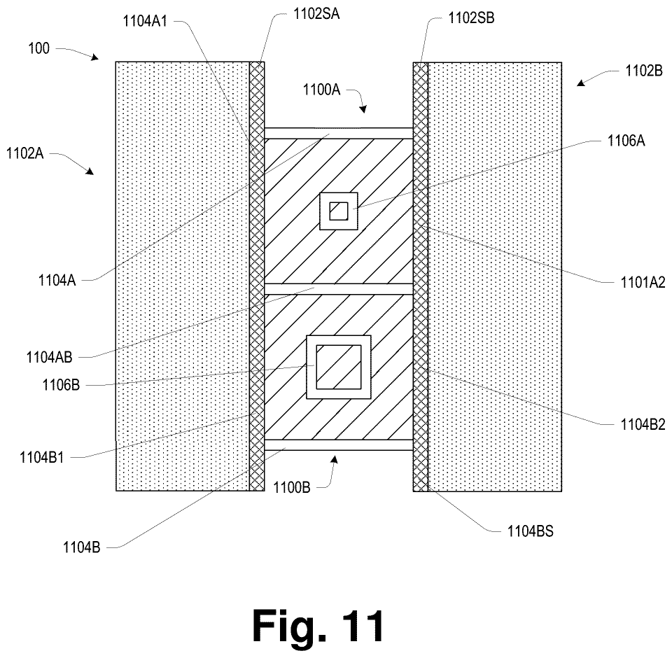

Referring to FIG. 11, the semiconductor structure 100 includes alignment regions 1100A, 1100B abutting two product regions 1102A, 1102B, in accordance with some embodiments. The product regions 1102A, 1102B comprise seal rings 1102SA, 1102SB and one or more semiconductor devices, such as memory devices, logic devices, etc. The alignment regions 1100A, 1100B include frames 1104A, 1104B at the edges of the alignment regions 1100A, 1100B and alignment marks 1106A, 1106B inside the frames 1104A, 1104B. Where the alignment regions 1100A, 1100B abut one another in the vertical direction, the frame segment 1104AB is shared by both alignment regions 1100A, 1100B. Where the alignment regions 1100A, 1100B abut the product regions 1102A. 1102B, portions of the seal rings 1102SA, 1102SB define frame segments 1104A1, 1104A2, 1104B1, 1104B2 of the frames 1104A, 1104B.

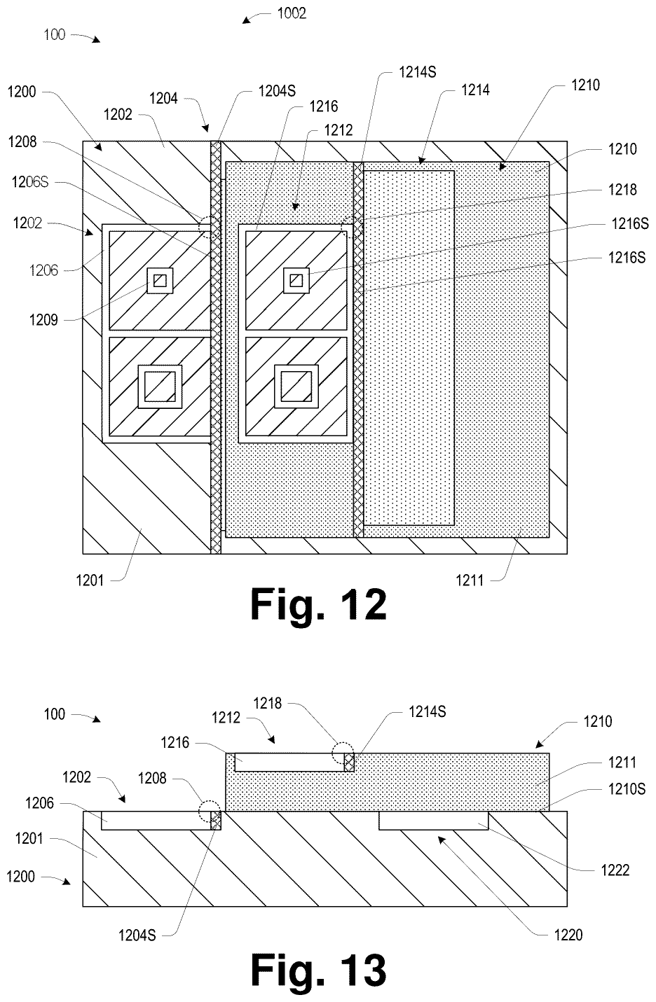

Referring to FIGS. 12 and 13, the frames around the edges of the alignment regions may be used for alignment and bonding for stacked semiconductor wafers, in accordance with some embodiments. Referring to FIG. 12, a first semiconductor wafer 1200 includes an alignment region 1202 abutting a product region 1204 with a seal ring 1204S formed in a substrate layer 1201. A frame 1206 around edges of the alignment region 1202 includes a segment 1206S of the seal ring 1204S. A frame-seal interface at a corner of the frame 1206 adjacent the seal ring 1204S provides an alignment reference 1208. An alignment mark 1209 is formed inside the frame 1206. A second semiconductor wafer 1210 includes an alignment region 1212 abutting a product region 1214 with a seal ring 1214S formed in a substrate layer 1211. A frame 1216 around edges of the alignment region 1212 includes a segment 1216S of the seal ring 1214S. A frame-seal interface at a corner of the frame 1216 adjacent the seal ring 1214S provides an alignment reference 1218. An alignment mark 1219 is formed inside the frame 1216.

Referring to FIG. 13, the second semiconductor wafer 1210 is stacked over the first semiconductor wafer 1200, in accordance with some embodiments. The alignment reference 1208 defined by the frame 1206 of the first semiconductor wafer 1200 may be aligned with the alignment reference 1218 defined by the frame 1216 of the second semiconductor wafer 1210 to control the vertical placement of the second semiconductor wafer 1210 by a tool. A second alignment region 1220 on the first semiconductor wafer 1200 is under the second semiconductor wafer 1210 and contacts a bottom surface 1210S of the second semiconductor wafer 1210. The second alignment region 1220 includes a frame 1222. As described in reference to FIG. 1, the frame 1222 includes a cap layer that may be a dielectric layer, such as silicon nitride, or a metal-containing layer, such as a metal silicide. The second semiconductor wafer 1210 is bonded to first semiconductor wafer 1200 using a hybrid bonding process, where at least one of heat or pressure is applied to the second semiconductor wafer 1210 to form a bond. The frame 1222 forms a bond with the material of the bottom surface 1219S of the second semiconductor wafer 1210, such as a substrate material (e.g., silicon).

Forming frames along the edges of an alignment region containing an alignment mark may at least one of reduce photoresist loading, improve the alignment mark structure, or improve the alignment procedures performed using the alignment mark. These improvements may improve at least one of CD pitch stability, profile quality, or OPC effectiveness. The frames may also provide alignment features or bonding features for stacking semiconductor wafers.

According to some embodiments of the disclosure, a semiconductor structure includes a first alignment region defined in a substrate layer and a first frame at edges of the first alignment region. A first alignment mark is in the first alignment region and bordered by the first frame.

According to some embodiments of the disclosure, a method of fabricating a semiconductor structure includes forming an isolation structure over a substrate layer in a first alignment region. A process layer is formed over the isolation structure. A patterned mask is formed over the process layer. The process layer is patterned using the patterned mask as a template to form a first frame at edges of the first alignment region and a first alignment mark in the first alignment region and bordered by the first frame.

According to some embodiments of the disclosure, a method of fabricating a semiconductor structure includes forming a first seal ring in a first substrate layer in a first product region of a first semiconductor wafer. A first frame is formed at edges of a first alignment region of the first semiconductor wafer. A first alignment mark is formed in the first alignment region bordered by the first frame. A second seal ring is formed in a second substrate layer in a second product region of a second semiconductor wafer. A second frame is formed at edges of a second alignment region of the second semiconductor wafer. A second alignment mark is formed in the second alignment region bordered by the second frame. The second semiconductor wafer is aligned over the first semiconductor wafer using the first frame and the second frame. The first frame comprises a first segment of the first seal ring where the first alignment region abuts the first product region. The second frame comprises a second segment of the second seal ring where the second alignment region abuts the second product region. Aligning the second semiconductor wafer over the first semiconductor wafer using the first frame and the second frame includes aligning a first frame-seal interface of the first segment with a second frame-seal interface of the second segment.

The foregoing outlines features of several embodiments so that those of ordinary skill in the art may better understand various aspects of the present disclosure. Those of ordinary skill in the art should appreciate that they may readily use the present disclosure as a basis for designing or modifying other processes and structures for carrying out the same purposes and/or achieving the same advantages of various embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first.” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A semiconductor structure, comprising:
a first alignment region defined in a substrate layer;
a first frame at edges of the first alignment region; and
a first alignment mark in the first alignment region and bordered by the first frame.

2. The semiconductor structure of claim 1, wherein the first frame and the first alignment mark comprise raised features of a process layer.

3. The semiconductor structure of claim 1, wherein the first frame and the first alignment mark comprise recessed features in a process layer.

4. The semiconductor structure of claim 1, comprising:
a second frame inside the first frame, wherein the first alignment mark is inside the second frame.

5. The semiconductor structure of claim 1, wherein the first frame comprises spaced segments.

6. The semiconductor structure of claim 5, wherein the spaced segments comprise at least one of rectangular spaced segments or circular spaced segments.

7. The semiconductor structure of claim 1, comprising:
a second alignment region defined in the substrate layer adjacent the first alignment region;
a second frame at edges of the second alignment region; and
a second alignment mark in the second alignment region and bordered by the second frame, wherein a shared segment of the first frame and second frame is defined where the first alignment region abuts the second alignment region.

8. The semiconductor structure of claim 1, comprising:
a first product region having a first seal ring adjacent the first alignment region, wherein the first frame comprises a segment of the first seal ring where the first alignment region abuts the first product region.

9. The semiconductor structure of claim 8, comprising:
a second product region having a second seal ring adjacent the first alignment region, wherein the first frame comprises a segment of the second seal ring where the first alignment region abuts the second product region.

10. The semiconductor structure of claim 1, wherein a first spacing between the first frame and a first side of the first alignment mark equals a second spacing between the first frame and a second side of the first alignment mark opposite the first side.

11. A method of fabricating a semiconductor structure, comprising:
forming an isolation structure over a substrate layer in a first alignment region;
forming a process layer over the isolation structure;
forming a patterned mask over the process layer; and
patterning the process layer using the patterned mask as a template to form a first frame at edges of the first alignment region and a first alignment mark in the first alignment region and bordered by the first frame.

12. The method of claim 11, wherein patterning the process layer comprises:
removing material of the process layer to define the first frame and the first alignment mark from raised portions of the process layer.

13. The method of claim 11, wherein patterning the process layer comprises:
removing material of the process layer to define a first recess that defines the first frame and a second recess that defines the first alignment mark.

14. The method of claim 11, comprising
patterning the process layer to form a second frame inside the first frame, wherein the first alignment mark is inside the second frame.

15. The method of claim 11, wherein patterning the process layer to form the first frame comprises:
patterning the process layer to define spaced segments that form the first frame.

16. The method of claim 15, wherein patterning the process layer to define spaced segments comprises:
patterning the process layer to define at least one of rectangular spaced segments or circular spaced segments.

17. The method of claim 11, comprising:
patterning the process layer using the patterned mask as a template to form a second frame at edges of a second alignment region and a second alignment mark in the second alignment region and bordered by the second frame, wherein the first frame and the second frame comprise a shared segment where the first alignment region abuts the second alignment region.

18. The method of claim 11, comprising:
forming a seal ring in the substrate layer in a product region adjacent the first alignment region, wherein the first frame comprises a segment of the seal ring where the first alignment region abuts the product region.

19. A method of fabricating a semiconductor structure, comprising:
forming a first seal ring in a first substrate layer in a first product region of a first semiconductor wafer;
forming a first frame at edges of a first alignment region of the first semiconductor wafer;
forming a first alignment mark in the first alignment region bordered by the first frame;
forming a second seal ring in a second substrate layer in a second product region of a second semiconductor wafer;
forming a second frame at edges of a second alignment region of the second semiconductor wafer;
forming a second alignment mark in the second alignment region bordered by the second frame; and
aligning the second semiconductor wafer over the first semiconductor wafer using the first frame and the second frame, wherein:
the first frame comprises a first segment of the first seal ring where the first alignment region abuts the first product region,
the second frame comprises a second segment of the second seal ring where the second alignment region abuts the second product region, and
aligning the second semiconductor wafer over the first semiconductor wafer using the first frame and the second frame comprises aligning a first frame-seal interface of the first segment with a second frame-seal interface of the second segment.

20. The method of claim 19, comprising:
forming a third frame at edges of a third alignment region of the first semiconductor wafer;
forming a third alignment mark in the third alignment region bordered by the third frame; and
bonding the second semiconductor wafer to the first semiconductor wafer, wherein:
the third frame is under the second semiconductor wafer, and
the third frame forms a hybrid bond to the second semiconductor wafer.
